(19) United States
(12) Patent Application Publication
(10) Pub. No.: US 2026/0122761 A1
(43) Pub. Date: Apr. 30, 2026

(54) ELECTRONIC DEVICE AND METHOD FOR ASSEMBLING ELECTRONIC DEVICE

(71) Applicant: DENSO CORPORATION, Kariya-city (JP)

(72) Inventor: Kazuya HIRASAWA, Kariya-city (JP)

(21) Appl. No.: 19/345,600

(22) Filed: Sep. 30, 2025

(30) Foreign Application Priority Data
Oct. 31, 2024 (JP) 2024-191918

(51) Int. Cl. H05K 1/02; H05K 3/34; H05K 7/20

(52) U.S. Cl. CPC H05K 1/0203; H05K 3/3436; H05K 7/20254; H05K 2201/10378; H05K 2201/10522

(57) ABSTRACT

An electronic device includes a housing, a substrate, a package component, a heat dissipating member, and an adhesive. The substrate is provided in the housing. The package component is mounted on the substrate and includes an interposer, a chip provided on the interposer, and a stiffener provided on the interposer. The heat dissipating member is compressible and disposed between the chip and the housing. The adhesive is disposed between the stiffener and the housing. The adhesive is shrunk by curing.

### CROSS REFERENCE TO RELATED APPLICATION

This application is based on and incorporates herein by reference Japanese Patent Application No. 2024-191918 filed on Oct. 31, 2024.

### TECHNICAL FIELD

The present disclosure relates to an electronic device including, for example, a chip.

### BACKGROUND

Conventionally, there is a technique of mounting a semiconductor chip on a substrate and using a heat sink to efficiently release a heat from the semiconductor chip.

### SUMMARY

According to at least oner embodiment of the present disclosure, an electronic device includes a housing, a substrate, a package component, a heat dissipating member, and an adhesive. The substrate is provided in the housing. The package component is mounted on the substrate and includes an interposer, a chip provided on the interposer, and a stiffener provided on the interposer. The heat dissipating member may be compressible and disposed between the chip and the housing. The adhesive may be disposed between the stiffener and the housing, and shrunk by curing.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a cross-sectional view showing a schematic structure of an electronic device according to a first embodiment.

FIG. 2 is a cross-sectional view showing the electronic device in which an area around a package component of the electronic device is enlarged.

FIG. 3 is a bottom view showing a box body of a housing as viewed from an opening of the box body.

FIG. 4 is an explanatory view showing an arrangement of a cover, a heat sink, and an interposer, as viewed in a thickness direction of the electronic device.

FIG. 5A is a planar view showing a package component as viewed from above.

FIG. 5B is a planar view showing the package component, on which an adhesive is applied to a part of a stiffener, as viewed from above.

FIG. 5C is a planar view showing the package component, on which an adhesive is applied to an entire periphery of the stiffener, as viewed from above.

FIG. 6A is a planar view showing the heat sink as viewed from below.

FIG. 6B is a planar view showing the heat sink with a groove, as viewed from below.

FIG. 7 is a cross-sectional view showing a schematic structure of an electronic device according to a second embodiment.

FIG. 8 is a perspective view showing a lower side of an integrated lid.

FIG. 9 is a cross-sectional view showing a part of an electronic device according to a modified example.

### DETAILED DESCRIPTION

According to a comparative example, there is a technique of mounting a semiconductor chip on a substrate and using a heat sink to efficiently release a heat from the semiconductor chip. For example, a technique is known in which a semiconductor chip is mounted on a substrate, a heat sink is placed on a surface of the semiconductor chip, and the heat sink is secured to the substrate using a leaf spring, a screw, or the like.

However, as a result of detailed studies by the inventor, the following matter has been found in the conventional technique.

The above-mentioned technique has a configuration in which a support column is provided on the substrate and the heat sink is secured using the leaf spring or the screw to improve heat dissipating performance. This configuration may complicate a structure of the electronic device.

In contrast to the comparative example, according to the present disclosure, a technique is capable of achieving high heat dissipation performance with a simple configuration.

An aspect of the present disclosure includes a housing, a substrate provided in the housing, a package component a heat dissipating member, and an adhesive. The package component is mounted on the substrate and includes an interposer, a chip provided on the interposer, and a stiffener provided on the interposer.

Furthermore, the present disclosure may include a heat sink thermally connected to the housing. The heat dissipating member is compressible and disposed between the chip and the housing, or between the chip and the heat sink. The adhesive is disposed between the stiffener and the housing, or between the stiffener and the heat sink. The adhesive is shrunk by curing.

In the present disclosure, the compressible heat dissipating member is interposed between the chip and the housing or between the chip and the heat sink. The adhesive shrinking upon curing bonds the stiffener to the housing or the stiffener to the heat sink. When the stiffener is bonded to the housing or the heat sink by the adhesive in the above-described configuration, the chip presses the heat dissipating member to be compressed, and accordingly, the heat dissipating member becomes in close contact with the housing or the heat sink due to shrinkage of the adhesive upon curing. In other words, the heat dissipating member becomes in close contact with the housing or the heat sink while being pressed by the chip. Therefore, even with such a simple configuration, high heat dissipating performance can be achieved.

Another aspect of the present disclosure is a method for manufacturing an electronic device.

In the method for manufacturing the electronic device, a heat dissipating member is disposed between a chip and a housing or between the chip and a heat sink. The chip is provided on the interposer of a package component mounted on a substrate in the housing. The heat sink is thermally connected to the housing. The heat dissipating member is compressible. An adhesive having a property that shrinks upon curing is applied between a stiffener and the housing or between the stiffener and the heat sink. The stiffener is provided on the interposer. The heat dissipating member is compressed by the chip and the housing due to shrinkage of the adhesive upon curing.

When the stiffener is bonded (i.e., joined) to the housing or the heat sink by the adhesive in the above-described configuration, the heat dissipating member is pressed by the chip and the housing, thereby being compressed and becoming in close contact with the housing or the heat sink due to the shrinkage of the adhesive (i.e., the adhesive applied to a joint target such as the stiffener, the housing, and the heat sink). In other words, the heat dissipating member becomes in close contact with the housing or the heat sink while being pressed by the chip and the housing. Therefore, even with such a simple configuration, high heat dissipating performance can be achieved.

Additionally, the order of the step of disposing the compressible heat dissipating member between the chip and the housing or between the chip and the heat sink, and the step of applying the adhesive, having the property that shrinks upon curing, between the stiffener and the housing or between the stiffener and the heat sink, may be in either order.

The exemplary embodiments of the present disclosure will be described below with reference to the drawings.

The embodiments of the present disclosure will be described below with reference to the drawings. In the following embodiments, portions that are the same as or equivalent to those described in a preceding embodiment are denoted by the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

### First Embodiment

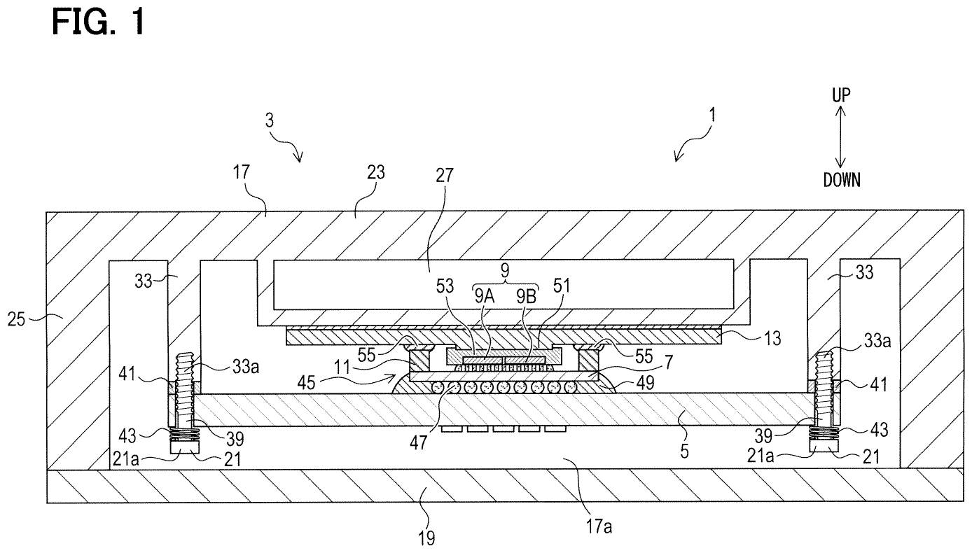

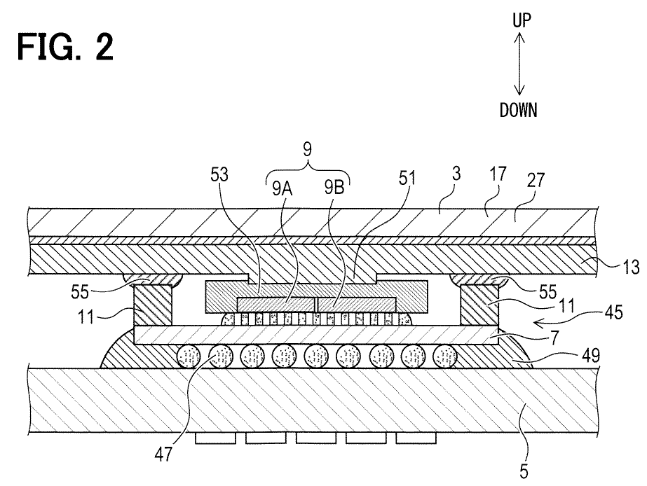

As shown in FIGS. 1 and 2, an electronic device (e.g., electronic control device) 1 includes, for example, a housing 3, a substrate 5, an interposer 7, multiple chips 9 (e.g., chip 9A, 9B), a stiffener 11, and a heat sink 13.

The housing 3 has a rectangular parallelepiped shape and includes a box body 17 and a lid 19. The substrate 5 is arranged inside the housing 3 and secured to the housing 3 with multiple fasteners 21. The interposer 7 is mounted on the substrate 5. The multiple chips 9 are mounted on the interposer 7. The chips 9 are heat-generating components, such as semiconductor chips.

Hereinafter, as shown in FIG. 1, in a thickness direction of the substrate 5, one side of the substrate 5 facing the heat sink 13 is referred to as an upper side, the other side of the substrate 5 facing the lid 19 is referred to as a lower side. The view in the thickness direction (i.e. up-down direction in FIG. 1) is referred to as an “A view”.

Hereinafter, each configuration will be described in detail. As shown in FIG. 1, the box body 17 of the housing 3 includes a plate-shaped portion 23 which has a rectangular shape in the A view, and a side portion 25 surrounding the plate-shaped portion 23. The box body 17 has an opening 17a on its lower side. The box body 17 is, for example, a die-casting product made of an aluminum alloy. The lid 19 is a plate member which has a rectangular shape in the A view and covers the opening 17a of the box body 17. The lid 19 may be made of a material such as an aluminum alloy or iron.

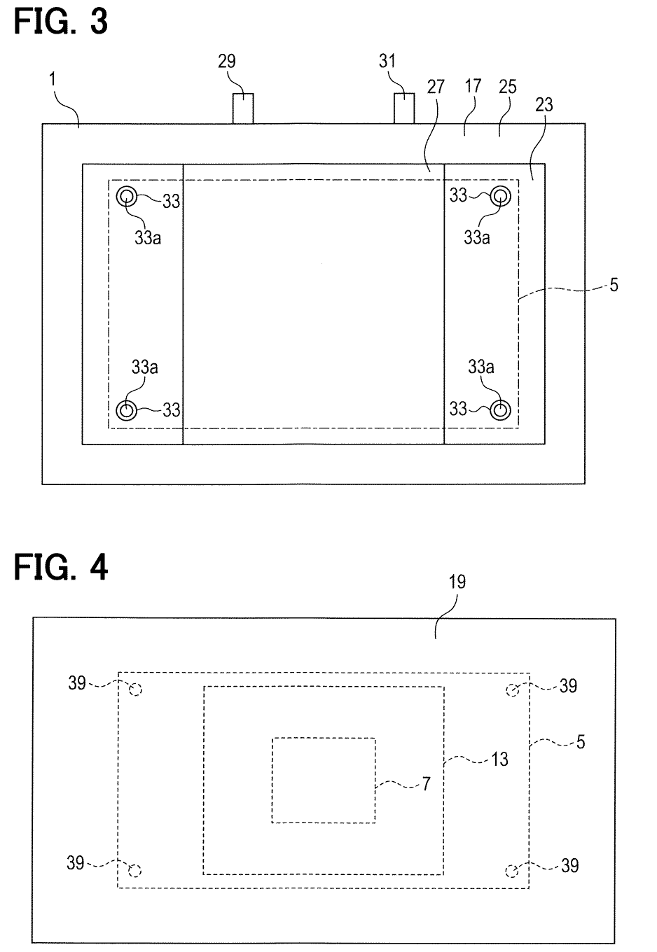

A cooling section 27 is provided on the lower side of a central portion of the plate-shaped portion 23 of the box body 17. The cooling section 27 has a rectangular parallelepiped shape, protrudes from the lower side of the plate-shaped portion 23, and is integrated with the box body 17. The cooling section 27 is, for example, a cooler which has a water-cooling structure. Specifically, the cooling section 27 is a protruding portion that protrudes downward from the central portion of the lower side of the plate-shaped portion 23. A cavity is formed in an interior of the cooling section 27, and cooling water, which serves as a coolant, is allowed to flow into the interior of the cooling section 27. As shown in FIG. 3, the side portion 25 of the box body 17 includes an inlet 29 and an outlet 31 for the cooling water.

As shown in FIG. 1, the heat sink 13 is a plate-shaped member used to efficiently transfer a heat generated from the chips 9 to the cooling section 27, and is made of, for example, metal such as copper having high thermal conductivity. An upper face of the heat sink 13 and a lower face of the cooling section 27 are bonded together with an adhesive, such as solder or a resin, having high heat dissipating performance.

As shown in FIGS. 1 and 3, four columns 33, which are used to fix the substrate 5, extend downward from the lower face of the plate-shaped portion 23 of the box body 17. As shown in FIG. 3, the columns 33 are positioned at four corners of the plate-shaped portion 23 (i.e., at positions corresponding to four vertices of the rectangular shape) in the A view. At an end of each of the columns 33, a screw hole 33a is provided, into which a tip end of a fastener 21 securing the substrate 5 is screwed.

The substrate 5 is a known printed circuit board (i.e., PCB) and has a rectangular shape in the A view. As shown in FIG. 4, at the four corners of the substrate 5, fastening through-holes 39 through which the fasteners 21 are passed are provided.

The fasteners 21 are positioned at the positions of the fastening through-holes 39 that are the four corners of the substrate 5, to secure the substrate 5 to the box body 17 of the housing 3. In other words, the fasteners 21 are positioned at positions corresponding to vertices of the rectangular shape of the substrate 5 in the A view.

Here, a structure securing the substrate 5 will be described. As shown in FIG. 1, the substrate 5 is secured to the four columns 33, which are erected on the box body 17, with the four fasteners 21. Each of the fasteners 21 is a screw having a head 21a. Specifically, a washer 41 is provided between a column 33 and the upper face of the substrate 5, and a spring 43 is provided between the lower face of the substrate 5 and the head 21a of the fastener 21. For example, the washer 41 may be a spring washer or a resin member having an elasticity.

The tip end of the fastener 21 is passed through a fastening through-hole 39 via the spring 43 and screwed into a screw hole 33a of the column 33 via the washer 41 so as to secure the substrate 5 to the box body 17. The spring 43 or the washer 41 can be omitted.

Next, a structure of the central portion of the substrate 5 will be described. As shown in FIGS. 1 and 2, in the A view, a component integrally formed by the interposer 7, the stiffener 11, the chips 9, and the like is provided on the central portion of the upper face of the substrate 5. Here, this integrated structure is referred to as a package component (e.g., semiconductor package) 45.

The interposer 7 includes a wiring that electrically connects the multiple chips 9 to each other, and a wiring that electrically connects the multiple chips 9 to the substrate 5. The interposer 7 and the substrate 5 are electrically connected via solder balls 47 (i.e., BGA solder) arranged in a grid pattern. Additionally, a side fill 49 is provided between the interposer 7 and the substrate 5, and on a periphery of the interposer 7. The side fill 49 reinforces a bonding strength between the interposer 7 and the substrate 5.

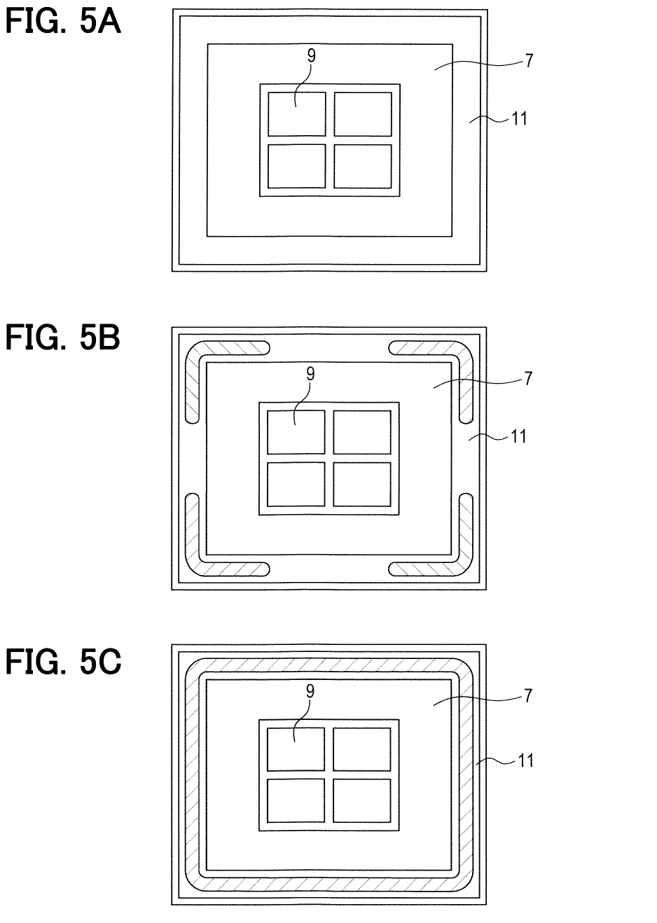

As shown in FIG. 5A, the stiffener 11 is made of, for example, copper, and is a reinforcing member for increasing a rigidity of the interposer 7. The stiffener 11 is bonded to the upper face of the interposer 7 and extends along an outer periphery of the interposer 7. In other words, the stiffener 11 has a quadrilateral-framed shape and is positioned at a location shown in FIG. 5A to be overlapped with the interposer 7 in the A view.

Specifically, a shape and dimension of the stiffener 11 are set such that the entire of an outer periphery of the stiffener 11 is positioned inward of the outer periphery of the interposer 7. In other words, the stiffener 11 is slightly smaller in size than the interposer 7. The multiple chips 9 are arranged so that each entire periphery (i.e., outer periphery) is surrounded by the stiffener 11 having the quadrilateral-framed shape.

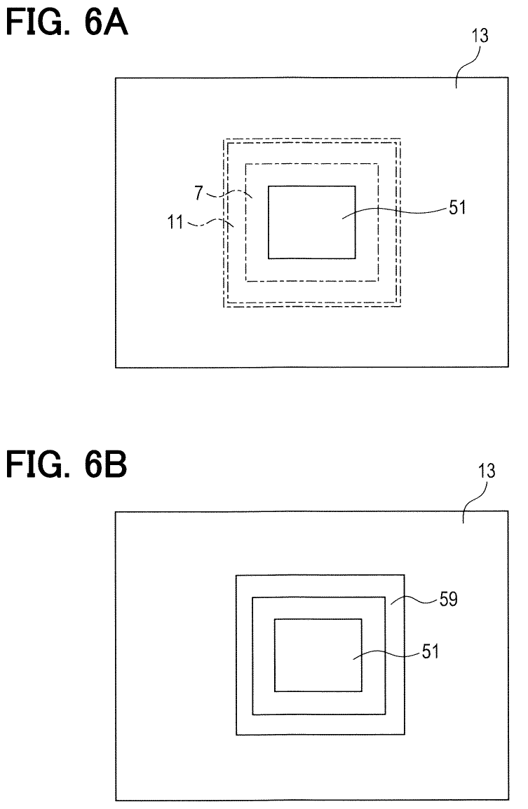

As shown in FIG. 6A, the heat sink 13 is a rectangular plate material in the A view. The heat sink 13 may be made of metal having high heat dissipating performance such as copper or a copper alloy. The heat sink 13 is joined (i.e., integrally secured) to a lower face of the cooling section 27 using a joint member such as solder having high heat dissipating performance.

On the central portion of the heat sink 13 in the A view, a rectangular plate-shaped protruding portion 51 is provided to protrude downward. In FIG. 6A, the heat sink 13 is illustrated as a shape viewed from the lower side of the electronic device 1, and the interposer 7 and the stiffener 11 are illustrated to be overlapped with each other. As shown in FIG. 6A, in the A view, the protruding portion 51 of the heat sink 13 is positioned on a central portion of the interposer 7 and is surrounded by the stiffener 11.

As shown in FIGS. 1 and 2, between the multiple chips 9 and the heat sink 13, a heat dissipating member 53 such as a compressible gel is provided. Specifically, the heat dissipating member 53, sandwiched between the multiple chips 9 and the protruding portion 51 of the heat sink 13, is in close contact with the multiple chips 9 and the protruding portion 51 while being pressed by them.

Additionally, an area of the heat dissipating member 53 in the A view is larger than an area of the protruding portion 51. Therefore, a thickness of a portion of the heat dissipating member 53 compressed by the protruding portion 51 is thinner than a thickness of a portion of the heat dissipating member 53 around a periphery of the protruding portion 51. In other words, a central portion of the heat dissipating member 53, being in contact with the protruding portion 51, is recessed.

The heat dissipating member 53 may be, for example, a compressible and gel-like heat dissipating resin (i.e., known heat dissipating gel). For example, the heat dissipating member 53 may be a silicone resin, an epoxy resin, or an acrylic resin. These resins may contain fillers having a high thermal conductivity, such as alumina particles.

Furthermore, an upper face of the quadrilateral frame-shaped stiffener 11 is joined to the lower face of the heat sink 13 using an adhesive (i.e., adhesive layer 55) that shrinks upon curing. Since the stiffener 11 is quadrilateral-framed shaped, the stiffener 11 surrounds the protruding portion 51 of the heat sink 13, and is joined to the heat sink 13 by the adhesive at a quadrilateral frame-shaped range of the heat sink 13, which faces the stiffener 11.

This adhesive may adopt an adhesive (e.g., adhesive containing a thermosetting resin) having a property of shrinking and curing upon heating. Specifically, a thermosetting adhesive such as a thermosetting epoxy resin can be used. The cure shrinkage rate of this thermosetting epoxy resin adhesive is 2 to 3% by volume. The thermosetting adhesive may adopt an adhesive composed of a thermosetting epoxy resin or an adhesive in which a main component is the thermosetting epoxy resin (e.g., the main component accounts for 50% by volume or more), i.e., an adhesive made of the thermosetting epoxy resin.

As long as the adhesive has a property of shrinking during bonding (i.e., curing), various types of adhesives that are not thermosetting (e.g., acrylic adhesive) can be used as the adhesive layer 55.

Next, a configuration compressing the heat dissipating member 53 will be described. In the present first embodiment, the heat dissipating member 53, such as a compressible gel, is positioned between the multiple chips 9 and the protruding portion 51 of the heat sink 13. Additionally, the lower face of the heat sink 13 and the upper face of the stiffener 11 are joined to each other by the adhesive having the property of shrinking and curing during bonding (i.e., property of shrinking upon curing).

During manufacturing of the electronic device 1, for example, the adhesive having the property of shrinking upon curing is applied to the upper face of the stiffener 11, the heat dissipating member 53 is interposed between the multiple chips 9 and the protruding portion 51 of the heat sink 13, and the adhesive between the heat sink 13 and the stiffener 11 is cured. When the adhesive made of the thermosetting epoxy resin is used, the adhesive is cured by heating to adhere the heat sink 13 and the stiffener 11.

Since the adhesive shrinks upon curing, a distance between the heat sink 13 and the stiffener 11 becomes smaller. As a result, the heat dissipating member 53 is pressed by both of the heat sink 13 and the stiffener 11, thereby shrinking. Therefore, a thickness of the heat dissipating member 53 within its pressed area becomes thin (i.e., the heat dissipating member 53 is compressed).

As shown in FIG. 5B, a position where the adhesive is applied may be a portion of the upper face of the stiffener 11, such as four corners of the quadrilateral frame-shaped stiffener 11 (i.e., shaded portions). As shown in FIG. 5C, a position where the adhesive is applied may be the entire of the upper face of the stiffener 11 (i.e., a shaded portion that has quadrilateral-framed shape).

Next, a structure pressing the substrate 5 will be described. As described below, the substrate 5 is pressed upward by the fastener 21. Additionally, the substrate 5 is placed at a position pressing the package component 45 toward the heat sink 13 in a thickness direction of the substrate 5 (i.e., up-down direction).

As shown in FIG. 1, the substrate 5 is secured to the four columns 33 erected on the plate-shaped portion 23 of the box body 17 by the four fastener 21. Specifically, since the fasteners 21 are secured to the columns 33 via washers 41 and springs 43 having the elasticity (i.e., in a state where the substrate 5 is interposed between the washers 41 and the springs 43), the substrate 5 is secured to the lower side of the column 33 while being pressed upward in FIG. 1.

Since the washers 41 and the springs 43 are compressed by the fasteners 21 being screwed, the substrate 5 can be moved slightly upward in the state where the substrate 5 is pressed upward. As a result, the substrate 5 and components placed on the upper face of the substrate 5, such as the package component 45 and the heat sink 13, can be pressed upward in FIG. 1.

Accordingly, even if the heat dissipating member 53 is compressed due to the shrinkage of the adhesive upon curing and the package component 45 and the like are moved upward in FIG. 1, the package component 45 and the like are firmly secured to the substrate 5.

Next, a method of manufacturing the electronic device 1 will be briefly described. The method described below is one example, various manufacturing methods that can manufacture the electronic device 1 described above are adoptable.

First, the box body 17 is placed such that the opening 17a faces upward. The heat sink 13 is placed on the surface of the cooling section 27 and joined with, for example, solder. Next, the heat dissipating member 53 is placed on the surface of the protruding portion 51 of the heat sink 13.

On the other hand, the package component 45 including the chips 9 and the stiffener 11 is placed on the substrate 5, and the package component 45 is soldered to the substrate 5 by reflow-soldering as well-known. Specifically, the solder balls 47 are heated and melt to join a wiring of the package component 45 and a wiring of the substrate 5 to be electrically conductive therebetween.

Next, an adhesive that shrinks upon curing is applied to the upper face of the stiffener 11. Alternatively, the adhesive may be applied to the surface of the heat sink 13 at a location where the stiffener 11 is positioned. Then, the substrate 5 is placed inside the box body 17 such that a face of the substrate 5 on which the package component 45 is mounted faces downward. At this time, the substrate 5 is placed such that positions of the chips 9 and the protruding portion 51 coincide with each other (i.e., the heat dissipating member 53 is interposed between the chips 9 and the protruding portion 51). Therefore, the adhesive on the upper face of the stiffener 11 is in contact with the heat sink 13.

After that, the stiffener 11 and the heat sink 13 are joined by curing of the adhesive. Furthermore, since the adhesive shrinks upon curing, the heat dissipating member 53 between the heat sink 13 and the chips 9 is compressed.

Next, the substrate 5 is secured to the box body 17 with the fasteners 21. After that, the lid 19 is secured to the box body 17.

Next, effects of the present first embodiment will be described.

The electronic device 1 according to the first embodiment includes the heat dissipating member 53 that can be compressed between the chips 9 and the heat sink 13. The stiffener 11 and the heat sink 13 are joined to each other with the adhesive that shrinks upon curing. Accordingly, when the stiffener 11 and the heat sink 13 are joined to each other with the adhesive, upon curing of the adhesive, the heat dissipating member 53 is compressed due to pressing by the chips 9 and is in close contact with the heat sink 13. In other words, the heat dissipating member 53 is in close contact with the heat sink 13 in a state of being pressed by the chips 9. Therefore, even with such a simple configuration, high heat dissipating performance can be achieved.

The electronic device 1 according to the first embodiment can adopt a thermal curing epoxy resin as the adhesive. Additionally, as a material of the heat sink 13, copper or a copper alloy can be adopted.

In the electronic device 1 according to the first embodiment, the stiffener 11 can be positioned so as to enclose the entire of each periphery of the multiple chips 9 in the A view, i.e., the outer peripheries of the multiple chips 9.

In the electronic device 1 according to the first embodiment, the stiffener 11 may be bonded to the heat sink 13 with the adhesive along the entire periphery of the stiffener 11. Only a portion of the stiffener 11 (e.g., a corner of the quadrilateral-framed shape or its periphery) may be joined to the heat sink 13.

In the electronic device 1 according to the first embodiment, when the substrate 5 is secured by the fasteners 21, the package component 45 and the heat sink 13 are pressed upward by the substrate 5. Accordingly, in the thickness direction of the substrate 5, the substrate 5 is located at a position pressing the package component 45 toward the heat sink 13 (e.g., a predetermined position in the thickness direction of the substrate 5). In other words, the substrate 5 presses the package component 45 toward the heat sink 13 by the substrate 5 itself. Additionally, the substrate 5 is pressed upward with the spring 43 when the fasteners 21 are screwed. The substrate 5 is movable in the up-down direction by an amount corresponding to the deflection of the washer 41.

Even if the package component 45 and the like move upward in FIG. 1 due to curing and shrinkage of the adhesive, this above-described configuration can prevent the package component 45 and the like from detaching from the substrate 5.

As shown in FIG. 6B, a quadrilateral frame-shaped groove 59, in the A view, may be provided on the lower face of the heat sink 13 so as to surround the periphery of the protruding portion 51 and face the quadrilateral frame-shaped stiffener 11. As a result, the adhesive can easily maintain its shape.

Next, a correspondence between the present disclosure and the present first embodiment will be described. An electronic device corresponds to the electronic device 1, a housing corresponds to the housing 3, a substrate corresponds to the substrate 5, an interposer corresponds to the interposer 7, a chip corresponds to the chips 9, chip 9A, chip 9B, a stiffener corresponds to the stiffener 11, a heat sink corresponds to the heat sink 13, a package component corresponds to the package component 45, a heat dissipating member corresponds to the heat dissipating member 53, and an adhesive corresponds to the adhesive layer 55.

### Second Embodiment

A basic configuration of a second embodiment is similar to that of the first embodiment, and hence differences from the first embodiment will be mainly described below. The same reference numerals as those in the first embodiment indicate the same configuration, and reference is made to the preceding description.

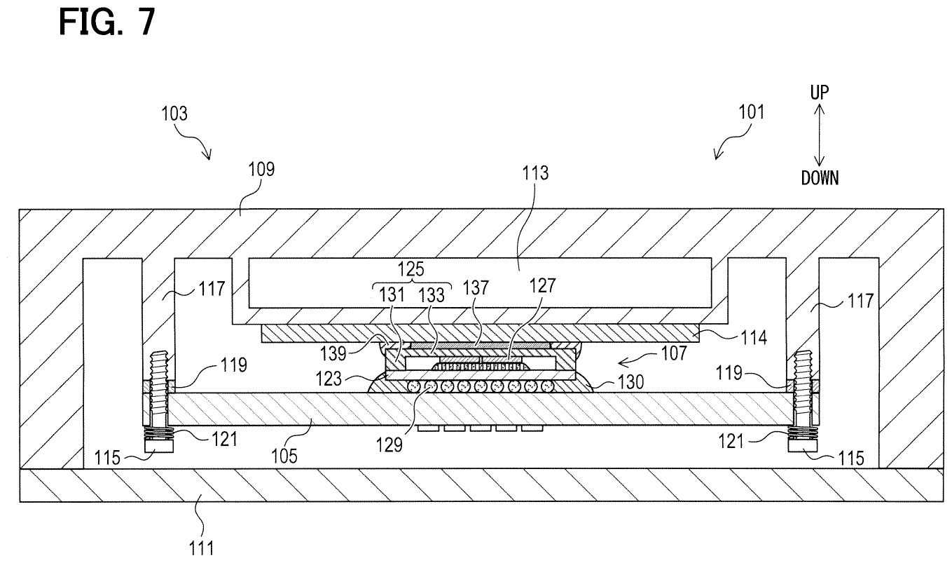

As shown in FIG. 7, an electronic device 101 according to the second embodiment includes, for example, a housing 103, a substrate 105, and a package component 107, similarly to the electronic device 1 according to the first embodiment. The housing 103 includes a box body 109 and a lid 111 as in the first embodiment. The box body 109 includes a cooling section 113. A heat sink 114 is bonded to the cooling section 113.

The substrate 105 is secured to four columns 117 with four fasteners (i.e., screw) 115 similarly to the first embodiment. The substrate 105 is secured to the columns 117 in a state of being interposed between washers 119 and springs 121.

The package component 107 includes an interposer 123, an integrated lid 125, multiple chips 127, and other components. The package component 107 is mounted on the substrate 105 with solder balls 129 arranged in an array pattern. A side fill 130 is positioned on a periphery of the interposer 123 and the solder balls 129.

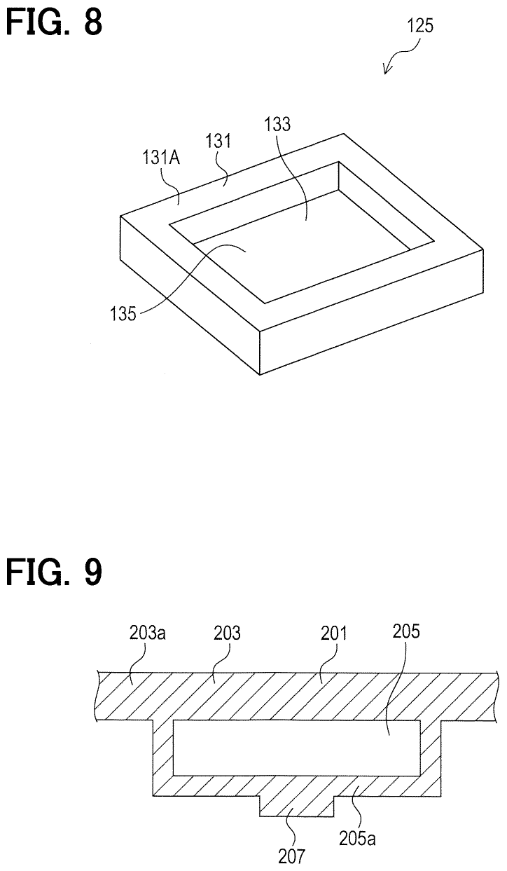

As shown in FIG. 8, the integrated lid 125 includes a quadrilateral frame-shaped stiffener 131 and a quadrilateral plate-shaped lid (i.e., lid) 133 that are integrated. The lid 133 is positioned on one side of the stiffener 131 in a thickness direction of the stiffener 131 to cover a central opening 135 of the stiffener 131. The integrated lid 125 is made of metal such as copper, and bonded via an adhesive to the interposer 123 on a face 131A of the stiffener 131 which is located on another side of the stiffener 131 in the thickness direction (i.e., upper side in FIG. 8).

As shown in FIG. 7, the multiple chips 127 mounted on the interposer 123 are positioned in a space enclosed by the interposer 123 and the integrated lid 125. The multiple chips 127 are joined to a lower face of the lid 133 by a joint member such as solder having a high heat dissipating performance.

A heat dissipating member 137 that is compressible and gel-like is positioned between an upper face of the lid 133 and a lower face of the heat sink 114, similarly to the first embodiment. Additionally, an upper face of the quadrilateral frame-shaped stiffener 131 of the integrated lid 125 is bonded to the lower face of the heat sink 114 via an adhesive having a property that shrinks upon curing (i.e., adhesive layer 139), similarly to the first embodiment.

The second embodiment has the same advantages as those of the first embodiment. Since the adhesive shrinks upon curing, the heat dissipating member 137 is compressed by the shrinkage force and is firmly adhered to the lid 133 and the heat sink 114. Therefore, high heat dissipating performance can be achieved by the simple configuration.

Although the embodiments of the present disclosure have been described above, the present disclosure is not limited to the embodiments described above, and various modifications can be made to implement the present disclosure.

In the present disclosure, the shapes of the substrate or the heat sink may be not only the rectangle but also other polygons. In other words, a planar shape is not specifically limited.

In the present disclosure, the number of fasteners is not limited four and may be multiple.

Although the preceding embodiments use a heat sink, the heat sink may be omitted. For example, as shown in FIG. 9, a box body 203 of a housing 201 may have a cooling section 205, and a protruding portion 207 having a shape like the protruding portion of the heat sink according to the first embodiment may be positioned on the cooling section 205, i.e., on a lower plate member 205a of the cooling section 205. Similarly to the first embodiment, a compressible heat dissipating member may be positioned between the protruding portion 207 and chips. In this case, a lower face of the cooling section 205 and an upper face of a stiffener are bonded by an adhesive that shrinks upon curing. The cooling section 205 may be omitted and the protruding portion 207 may be positioned on a lower face of a plate-shaped portion 203a of the box body 203. The protruding portion 207 may be omitted.

The cooling section may be integrated with the housing, and may be separated from the housing. If the cooling section is separated from the housing, for example, the housing and the cooling section may be joined so that an appropriate heat conduction can be established between the housing and the cooling section. As described above, the cooling section may be omitted.

Multiple functions of one element in the above embodiments may be implemented by multiple elements, or one function of one element may be implemented by multiple elements. Further, multiple functions of multiple elements may be implemented by one element, or one function implemented by multiple elements may be implemented by one element. A part of the configuration of each of the embodiments described above may be omitted. At least the part of the configuration of each of the embodiments described above may be added to or substituted for a configuration of another embodiment.

What is claimed is:

1. An electronic device, comprising:
a housing;
a substrate provided in the housing;
a package component mounted on the substrate, wherein the package component includes an interposer, a chip provided on the interposer, and a stiffener provided on the interposer;
a heat dissipating member that is compressible and disposed between the chip and the housing; and
an adhesive disposed between the stiffener and the housing, the adhesive being shrunk by curing.

2. The electronic device according to claim 1, wherein
the adhesive bonds the stiffener and the housing.

3. The electronic device according to claim 1, further comprising
a heat sink thermally connected to the housing, wherein
the heat dissipating member is disposed between the chip and the heat sink, and
the adhesive is disposed between the stiffener and the heat sink.

4. The electronic device according to claim 3, wherein
the adhesive bonds the stiffener and the heat sink.

5. The electronic device according to claim 1, wherein
the adhesive is made of a thermosetting epoxy resin.

6. The electronic device according to claim 1, wherein
the stiffener encloses an entire periphery of the chip.

7. The electronic device according to claim 6, wherein
the stiffener is bonded to the heat sink along an entire periphery of the stiffener by the adhesive.

8. The electronic device according to claim 1, wherein
the package component further includes a lid covering an opening of the package component that faces the housing, and
the stiffener is integrated with the lid.

9. The electronic device according to claim 3, wherein
the substrate presses the package component toward the heat sink as a pressing structure.

10. The electronic device according to claim 1, wherein
the heat sink is made of copper of a copper alloy.

11. The electronic device according to claim 1, wherein
the heat sink is integrally secured to the housing.

12. A method of manufacturing an electronic device, comprising:
disposing a heat dissipating member between a chip and a housing, the chip being provided on an interposer of a package component mounted on a substrate in the housing, the heat dissipating member being compressible;
applying an adhesive having a property that shrinks upon curing between a stiffener and the housing, the stiffener being provided on the interposer; and
compressing the heat dissipating member by the chip and the housing due to shrinkage of the adhesive upon curing.
